(19) United States
(12) Patent Application Publication
(10) Pub. No.: US 2026/0190333 A1
(43) Pub. Date: Jul. 2, 2026

(54) SEMICONDUCTOR STRUCTURE AND FORMING METHOD THEREFOR

(71) Applicant: CXMT Corporation, Hefei (CN)

(72) Inventors: Xiaojie Li, Hefei (CN); Yige Du, Hefei (CN)

(73) Assignee: CXMT Corporation, Hefei (CN)

(21) Appl. No.: 19/425,064

(22) Filed: Dec. 18, 2025

Related U.S. Application Data
(63) Continuation of application No. PCT/CN2025/115531, filed on Aug. 19, 2025.

(30) Foreign Application Priority Data
Dec. 30, 2024 (CN) 202411979486.8

(51) Int. Cl. H10B 12/00; H10D 1/00; H10D 1/68; H10W 20/41

(52) U.S. Cl. CPC H10B 12/50; H10B 12/482; H10D 1/043; H10D 1/714; H10W 20/435

(57) ABSTRACT

The semiconductor structure includes a semiconductor substrate, a stacked structure, and a bit line structure. The stacked structure includes separation layers and composite layers that are alternately stacked in the vertical direction. The bit line structure extends in the vertical direction and runs through the stacked structure. The semiconductor substrate includes an array region and a periphery region; and the stacked structure located in the periphery region includes a capacitor region. A row of bit line structures are formed outside each of two opposite sides of the capacitor region in a first direction. Each of the composite layers of the capacitor region includes first electrode plates. The first electrode plates are distributed at intervals on two opposite sides of the composite layer of the capacitor region in the first direction and protrude outward. Each of the first electrode plates is connected to a corresponding bit line structure.

This application is a continuation application of International Application No. PCT/CN 2025/115531, filed on Aug. 19, 2025, which is based on and claims priority of Chinese Patent Application No. 202411979486.8, filed with the China National Intellectual Property Administration on Dec. 30, 2024 and entitled “SEMICONDUCTOR STRUCTURE AND FORMING METHOD THEREFOR”. The above-referenced application is incorporated herein by reference in its entirety.

### TECHNICAL FIELD

The present disclosure relates to, but is not limited to, a semiconductor structure and a forming method therefor.

### BACKGROUND

A dynamic random access memory (Dynamic Random Access Memory, DRAM) is a semiconductor apparatus commonly utilized in electronic devices such as computers. A DRAM chip is divided into an array (Array) region and a periphery (Periphery) region, where the array region includes a memory cell array configured to store data, and the periphery region includes a periphery circuit located on a periphery of the memory cell array.

A capacitor in the periphery region is generally referred to as an NICAP. The NICAP needs a relatively large capacity to serve as a power supply or perform signal processing in the periphery region. However, in the prior art, the structure of the NICAP is relatively complex, and process costs are relatively high, and further optimization is needed.

### SUMMARY

In view of this, embodiments of the present disclosure provide a semiconductor structure and a forming method therefor, which can save costs and improve performance.

Technical solutions of the embodiments of the present disclosure are implemented as follows:
The embodiments of the present disclosure provide a semiconductor structure. The semiconductor structure includes a semiconductor substrate, a stacked structure, and a bit line structure; and the stacked structure and the bit line structure are located on the semiconductor substrate. The semiconductor substrate includes an array region and a periphery region; the stacked structure includes separation layers and composite layers that are alternately stacked in the vertical direction; and the bit line structure extends in the vertical direction and runs through the stacked structure. The stacked structure located in the periphery region includes a capacitor region; and a row of bit line structures are formed outside each of two opposite sides of the capacitor region in a first direction. Each of the composite layers of the capacitor region includes first electrode plates; the first electrode plates are distributed at intervals on two opposite sides of the composite layer of the capacitor region in the first direction and protrude outward; and each of the first electrode plates is connected to a corresponding bit line structure.

The embodiments of the present disclosure further provide a forming method for a semiconductor structure. The method includes: providing a semiconductor substrate, the semiconductor substrate including an array region and a periphery region; forming a stacked structure on the semiconductor substrate, the stacked structure including separation layers and composite layers that are alternately stacked in the vertical direction; and forming a bit line structure in the stacked structure and forming a capacitor region in the periphery region based on a first photomask. The bit line structure extends in the vertical direction and runs through the stacked structure; a row of bit line structures are formed outside each of two opposite sides of the capacitor region in a first direction; and each of the composite layers of the capacitor region includes first electrode plates; the first electrode plates are distributed at intervals on two opposite sides of the composite layer of the capacitor region in the first direction and protrude outward; and each of the first electrode plates is connected to a corresponding bit line structure.

### BRIEF DESCRIPTION OF DRAWINGS

FIG. 1 is a schematic diagram 1 of a structure of a semiconductor structure according to the embodiments of the present disclosure;

FIG. 2 is a schematic diagram 2 of a structure of a semiconductor structure according to the embodiments of the present disclosure;

FIG. 3A is a schematic diagram 1 of a structure corresponding to a forming method for a semiconductor structure according to the embodiments of the present disclosure;

FIG. 3B is a schematic diagram 2 of a structure corresponding to a forming method for a semiconductor structure according to the embodiments of the present disclosure;

FIG. 3C is a schematic diagram 3 of a structure corresponding to a forming method for a semiconductor structure according to the embodiments of the present disclosure;

FIG. 4A is a schematic diagram 4 of a structure corresponding to a forming method for a semiconductor structure according to the embodiments of the present disclosure;

FIG. 4B is a schematic diagram 5 of a structure corresponding to a forming method for a semiconductor structure according to the embodiments of the present disclosure;

FIG. 4C is a schematic diagram 6 of a structure corresponding to a forming method for a semiconductor structure according to the embodiments of the present disclosure;

FIG. 5A is a schematic diagram 7 of a structure corresponding to a forming method for a semiconductor structure according to the embodiments of the present disclosure;

FIG. 5B is a schematic diagram 8 of a structure corresponding to a forming method for a semiconductor structure according to the embodiments of the present disclosure;

FIG. 5C is a schematic diagram 9 of a structure corresponding to a forming method for a semiconductor structure according to the embodiments of the present disclosure;

FIG. 6A is a schematic diagram 10 of a structure corresponding to a forming method for a semiconductor structure according to the embodiments of the present disclosure;

FIG. 6B is a schematic diagram 11 of a structure corresponding to a forming method for a semiconductor structure according to the embodiments of the present disclosure;

FIG. 6C is a schematic diagram 12 of a structure corresponding to a forming method for a semiconductor structure according to the embodiments of the present disclosure;

FIG. 7A is a schematic diagram 13 of a structure corresponding to a forming method for a semiconductor structure according to the embodiments of the present disclosure;

FIG. 7B is a schematic diagram 14 of a structure corresponding to a forming method for a semiconductor structure according to the embodiments of the present disclosure;

FIG. 7C is a schematic diagram 15 of a structure corresponding to a forming method for a semiconductor structure according to the embodiments of the present disclosure;

FIG. 8A is a schematic diagram 16 of a structure corresponding to a forming method for a semiconductor structure according to the embodiments of the present disclosure;

FIG. 8B is a schematic diagram 17 of a structure corresponding to a forming method for a semiconductor structure according to the embodiments of the present disclosure;

FIG. 8C is a schematic diagram 18 of a structure corresponding to a forming method for a semiconductor structure according to the embodiments of the present disclosure;

FIG. 9A is a schematic diagram 19 of a structure corresponding to a forming method for a semiconductor structure according to the embodiments of the present disclosure;

FIG. 9B is a schematic diagram 20 of a structure corresponding to a forming method for a semiconductor structure according to the embodiments of the present disclosure;

FIG. 9C is a schematic diagram 21 of a structure corresponding to a forming method for a semiconductor structure according to the embodiments of the present disclosure;

FIG. 10A is a schematic diagram 22 of a structure corresponding to a forming method for a semiconductor structure according to the embodiments of the present disclosure;

FIG. 10B is a schematic diagram 23 of a structure corresponding to a forming method for a semiconductor structure according to the embodiments of the present disclosure;

FIG. 10C is a schematic diagram 24 of a structure corresponding to a forming method for a semiconductor structure according to the embodiments of the present disclosure;

FIG. 11A is a schematic diagram 25 of a structure corresponding to a forming method for a semiconductor structure according to the embodiments of the present disclosure;

FIG. 11B is a schematic diagram 26 of a structure corresponding to a forming method for a semiconductor structure according to the embodiments of the present disclosure;

FIG. 11C is a schematic diagram 27 of a structure corresponding to a forming method for a semiconductor structure according to the embodiments of the present disclosure;

FIG. 12A is a schematic diagram 28 of a structure corresponding to a forming method for a semiconductor structure according to the embodiments of the present disclosure;

FIG. 12B is a schematic diagram 29 of a structure corresponding to a forming method for a semiconductor structure according to the embodiments of the present disclosure; and

FIG. 12C is a schematic diagram 30 of a structure corresponding to a forming method for a semiconductor structure according to the embodiments of the present disclosure.

### DESCRIPTION OF EMBODIMENTS

To make the objectives, technical solutions, and advantages of the present disclosure clearer, the technical solutions of the present disclosure are further described in detail below with reference to the accompanying drawings and the embodiments. The described embodiments should not be considered as limitations to the present disclosure. All other embodiments obtained by a person of ordinary skill in the art without creative efforts fall within the scope of the present disclosure.

“Some embodiments” describing a subset of all possible embodiments is involved in the following descriptions. However, it may be understood that “some embodiments” may be the same subset or different subsets of all the possible embodiments, and may be combined with each other when there is no conflict.

The following descriptions are added if descriptions such as “first/second” appear in the application document. In the following descriptions, involved terms “first/second/third” are merely for distinguishing between similar objects and do not represent specific rankings of the objects. It may be understood that “first/second/third” may be interchanged for a specific sequence or order if allowed, so that the embodiments of the present disclosure described herein can be implemented in a sequence other than those shown or described herein.

In this specification, when a layer/element is referred to as being located “above” another layer/element, the layer/element may be located directly on the another layer/element, or an intermediate layer/element may exist between the two layers/elements. In addition, in an orientation, a layer/element is located “above” another layer/element, and when the orientation is reversed, the layer/element may be located “below” the another layer/element.

Unless otherwise defined, all technical and scientific terms adopted in this specification have meanings the same as those commonly understood by a person skilled in the art of the present disclosure. The terms adopted in this specification are merely intended to describe the embodiments of the present disclosure, but are not intended to limit the present disclosure.

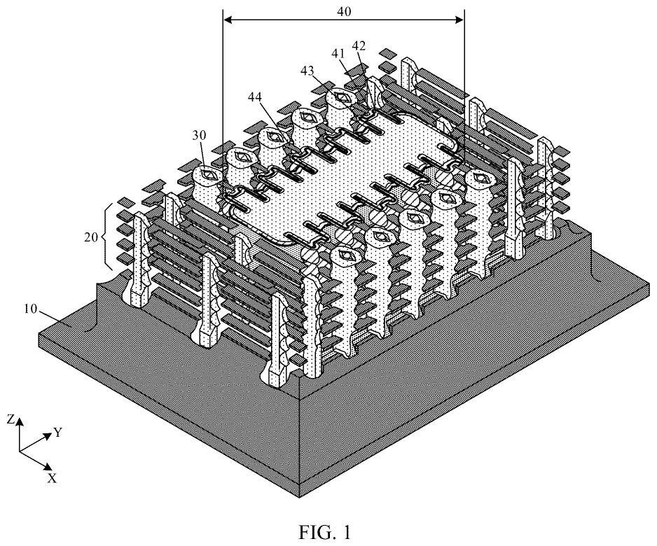

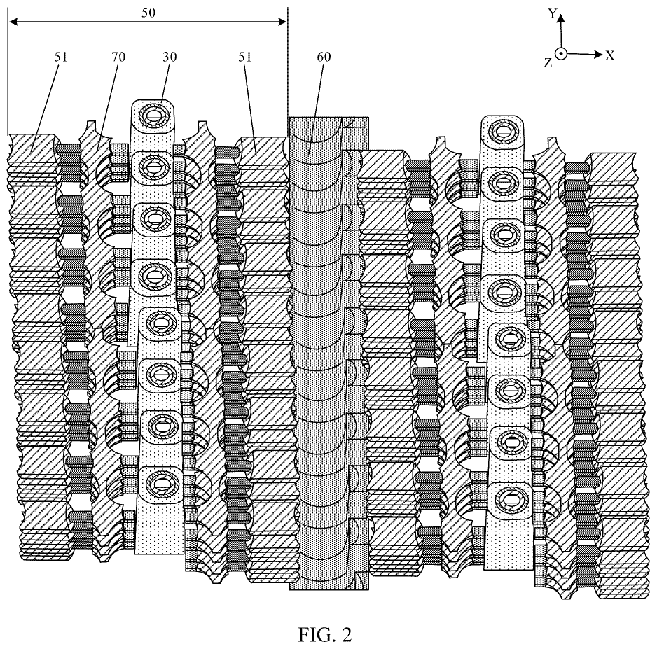

It should be noted that FIG. 1 and FIG. 2 are schematic diagrams of a semiconductor structure according to the embodiments of the present disclosure. Both FIG. 1 and FIG. 2 are schematic diagrams of structures from a three-dimensional perspective.

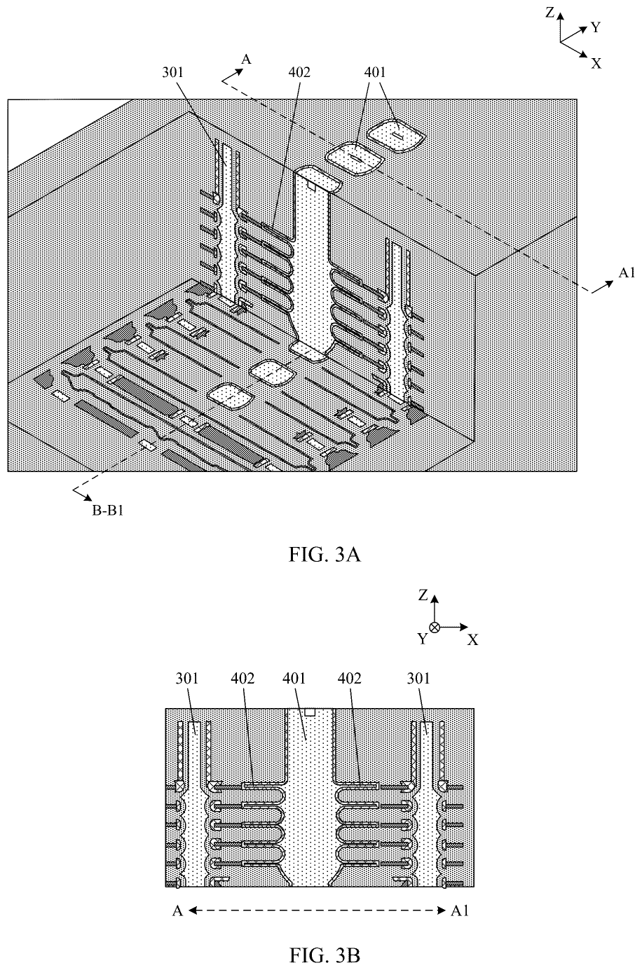

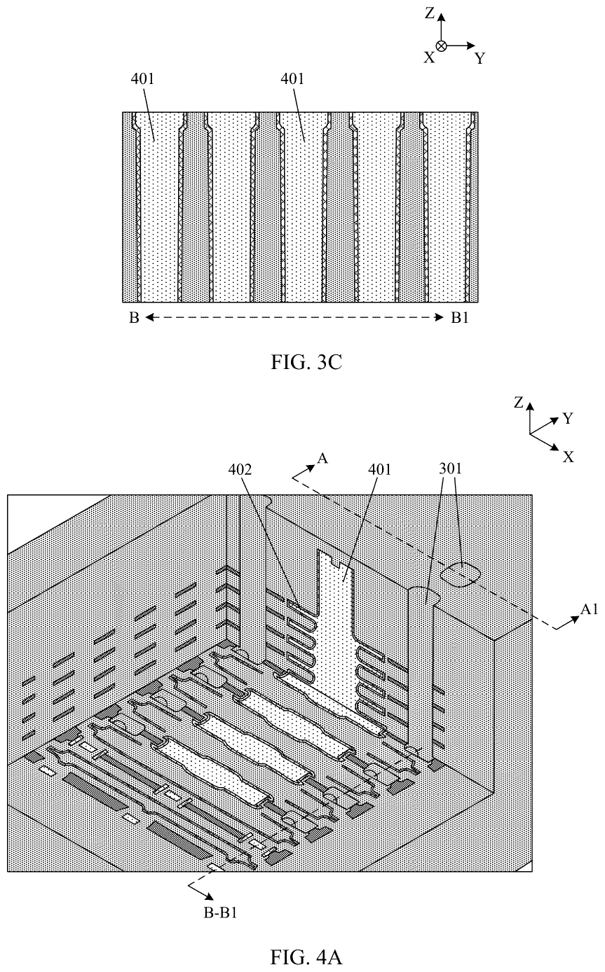

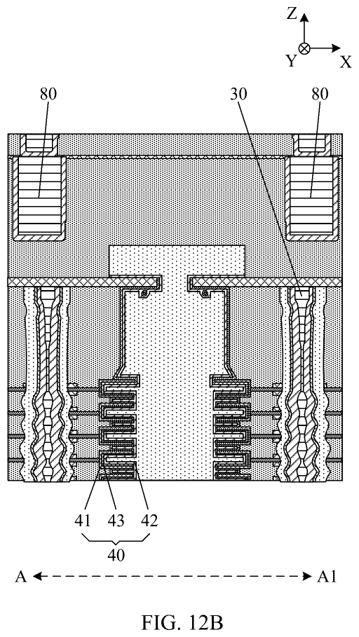

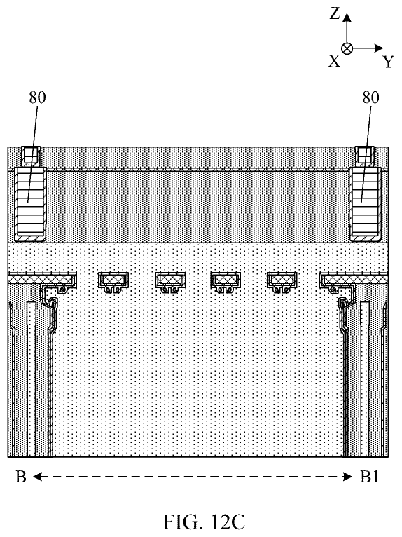

FIG. 3A, FIG. 3B, and FIG. 3C to FIG. 12A, FIG. 12B, and FIG. 12C are schematic diagrams of structures of various steps in a forming method for a semiconductor structure according to the embodiments of the present disclosure. A schematic diagram numbered A is a schematic diagram of a structure from a three-dimensional perspective, a schematic diagram numbered B is a schematic cross-sectional structural diagram along an A-A1 direction of a cutting line in the schematic diagram numbered A, and a schematic diagram numbered C is a schematic cross-sectional structural diagram along a B-B1 direction of a cutting line in the schematic diagram numbered A. In addition, for ease of description, an internal structure is cut open in the schematic diagram numbered A. However, in practice, a cut-open position is filled with a corresponding structure.

The embodiments of the present disclosure provide a semiconductor structure. As shown in FIG. 1, the semiconductor structure includes a semiconductor substrate 10, a stacked structure 20, and a bit line structure 30.

In the embodiments of the present disclosure, referring to FIG. 1, the stacked structure 20 and the bit line structure 30 are located on the semiconductor substrate 10. The stacked structure 20 includes separation layers and composite layers that are alternately stacked in the vertical direction Z. Devices and circuit structures are formed in the composite layers, and the separation layers are configured to separate the composite layers. The bit line structure 30 extends in the vertical direction Z and runs through the stacked structure 20. In this way, a 3D (three-dimensional) semiconductor structure is formed, thereby improving a degree of integration, improving performance, and reducing costs.

In the embodiments of the present disclosure, the semiconductor substrate 10 includes an array region and a periphery region. The array region includes a memory cell array configured to store data, and the periphery region includes a periphery circuit located on a periphery of the memory cell array. The stacked structure 20 located in the periphery region includes a capacitor region 40, and the capacitor region 40 is configured to form a capacitor NICAP in the periphery region. A region shown at a central position in FIG. 1 is the capacitor region 40.

It should be noted that, in a memory chip (such as a DRAM chip), the capacitor NICAP in the periphery region serves as a decoupling capacitor, and a main function of the decoupling capacitor is to provide a stable power supply, reduce power supply noise, and protect the chip from high-frequency electromagnetic interference. The decoupling capacitor not only can be disposed at a power supply end to serve as a local source for providing a transient current, so as to maintain stability of a power supply voltage, but also can bypass high-frequency noise to reduce high-frequency electromagnetic interference.

In the embodiments of the present disclosure, referring to FIG. 1, a row of bit line structures 30 are formed outside each of two opposite sides of the capacitor region 40 in a first direction X. The first direction X is located in a horizontal plane perpendicular to the vertical direction Z, that is, the first direction X is perpendicular to the vertical direction Z.

Still referring to FIG. 1, each of the composite layers of the capacitor region 40 includes first electrode plates 41. The first electrode plates 41 are distributed at intervals on two opposite sides of the composite layer of the capacitor region 40 in the first direction X. Adjacent first electrode plates 41 are not directly connected to each other.

Still referring to FIG. 1, each of the first electrode plates 41 protrudes toward an outer side of the capacitor region 40, that is, each of the first electrode plates 41 protrudes toward a corresponding bit line structure 30, and is connected to the corresponding bit line structure 30.

It can be understood that the first electrode plate 41 protrudes outward, which facilitates connection to the bit line structure 30 located on the outer side, thereby benefitting processing and manufacturing of the semiconductor structure. In addition, the first electrode plate 41 protrudes outward to form a curved electrode plate shape. In this way, an area between the electrode plates can be increased, and thus the capacity of the capacitor NICAP is increased.

In some embodiments of the present disclosure, referring to FIG. 1, the composite layer of the capacitor region 40 further includes a dielectric layer 43 and a second electrode plate 42. The second electrode plate 42 is located on an inner side of the composite layer of the capacitor region 40. The dielectric layer 43 is located between the first electrode plate and the second electrode plate.

An inner side of the second electrode plate 42 is filled with a semiconductor material, and the semiconductor material can play a supporting and isolating role. The semiconductor material may include polysilicon.

In the embodiments of the present disclosure, in a composite layer of each capacitor region 40, the second electrode plate 42 is an integral electrode plate, that is, a same second electrode plate 42 and multiple first electrode plates 41 form a capacitor. In this way, it is equivalent to connecting multiple capacitors in parallel, so that a capacitor with relatively large capacity can be implemented.

In addition, in a composite layer of each capacitor region 40, the second electrode plate 42 is located on the inner side to form a closed structure. In this way, a size occupied by a capacitor can be effectively reduced, thereby benefitting improvement of a degree of integration.

In the embodiments of the present disclosure, referring to FIG. 1, a surface of the bit line structure 30 in the vertical direction Z is in a wave shape, where the bit line structure 30 protrudes outward at a position at which the bit line structure 30 is connected to a contact. In this way, a contact area of the bit line structure 30 with the contact structure not only can be increased, which can reduce contact resistance, but also a cross-sectional area of the bit line structure 30 is enlarged, which can reduce resistance of the bit line structure 30.

In the embodiments of the present disclosure, referring to FIG. 1, the bit line structure 30 may include one or more layers of conductive material, where the conductive material may include one or more of titanium (Ti), titanium nitride (TiN), or tungsten (W). An etching selectivity ratio between the conductive material of the bit line structure 30 and a dielectric material has a relatively large difference. In this way, selective etching of the conductive material can be ensured to form the bit line structure 30. The dielectric material may be silicon nitride (SiN) or silicon oxide (SiO).

In the embodiments of the present disclosure, referring to FIG. 1, materials of the first electrode plate 41 and the second electrode plate 42 may include titanium (Ti) and/or titanium nitride (TiN). The material of the dielectric layer 43 may include a high-k (high-k) material, and the capacity of the capacitor can be increased by adopting the high-k material.

In some embodiments of the present disclosure, referring to FIG. 1, the composite layer of the capacitor region 40 further includes a contact plug 44. The contact plug 44 is located between the first electrode plate 41 and the bit line structure 30. Each of the first electrode plates 41 is connected to a corresponding bit line structure 30 through the contact plug 44.

It can be understood that the contact plug 44 can establish a good electrical connection between the first electrode plate 41 and the bit line structure 30, avoiding an open circuit due to poor contact. At a connection position between the contact plug 44 and the bit line structure 30, the bit line structure 30 protrudes outward, thereby increasing contact area and reducing contact resistance.

In some embodiments of the present disclosure, as shown in FIG. 2, the stacked structure located in the array region includes a memory cell region 50. Memory cells 51 arranged in an array are provided in the memory cell region 50.

In the embodiments of the present disclosure, referring to FIG. 2, one bit line structure 30 is formed between two opposite memory cells 51 in the first direction X, and the two memory cells 51 are connected to a corresponding bit line structure 30 (that is, the bit line structure 30 between the two memory cells 51).

In the embodiments of the present disclosure, referring to FIG. 2, an isolation structure 60 may be formed on a side that is of the memory cell 51 and that is away from the bit line structure 30. The isolation structure 60 runs through the stacked structure and extends in a second direction Y. In FIG. 2, the isolation structure 60 is shown as a cavity, in which a filled dielectric material is not drawn. The second direction Y is located in a horizontal plane perpendicular to the vertical direction Z, that is, the second direction Y is perpendicular to the vertical direction Z. In addition, the first direction X intersects the second direction Y, and an included angle therebetween is not limited.

In some embodiments of the present disclosure, with reference to FIG. 1 and FIG. 2, the capacitor region 40 and the memory cell region 50 are both formed based on a first photomask.

In FIG. 2, a projection of the memory cells 51 and the isolation structure 60 that are between two rows of bit line structures 30 on the horizontal plane is the same as a projection of the capacitor region 40 in FIG. 1 on the horizontal plane. In addition, the memory cell 51 shown in FIG. 2 may be a capacitor in the memory cell, and the capacitor in the memory cell and the capacitor (that is, the capacitor region 40) in the periphery region are formed in a same layer. Therefore, a same photomask can be adopted to form the capacitor region 40 and the memory cell region 50. In this way, a quantity of photomasks needed is reduced, and costs are saved.

In some embodiments of the present disclosure, referring to FIG. 2, the semiconductor structure further includes a word line structure 70. The word line structure 70 extends in the second direction Y, and is located between the memory cell 51 and the bit line structure 30.

In some embodiments of the present disclosure, referring to FIG. 12A, FIG. 12B, and FIG. 12C, the semiconductor structure further includes a back-end interconnect 80. The back-end interconnect 80 extends in the vertical direction Z. The back-end interconnect 80 is located above the capacitor region 40 and above the bit line structure 30. The material of the back-end interconnect 80 includes a metal material, such as tungsten (W).

The embodiments of the present disclosure further provide a forming method for a semiconductor structure, including steps S101 to S103.

In the step of S101, a semiconductor substrate 10 is provided.

In the embodiments of the present disclosure, referring to FIG. 1, the semiconductor substrate 10 is divided into an array region and a periphery region. The array region can be configured to form a memory cell array to store data, and the periphery region can be configured to form a periphery circuit located on a periphery of the memory cell array.

In the step of S102, a stacked structure 20 is formed on the semiconductor substrate 10.

In the embodiments of the present disclosure, referring to FIG. 1, the stacked structure 20 includes separation layers and composite layers that are alternately stacked in the vertical direction. Devices and circuit structures are formed in the composite layers, and the separation layers are configured to separate the composite layers. Through the stacked structure 20, a 3D semiconductor structure can be formed, thereby improving a degree of integration, improving performance, and reducing costs.

In the embodiments of the present disclosure, referring to FIG. 1, the stacked structure 20 may be generated layer by layer through an epitaxial growth process; or the stacked structure 20 may be generated by alternately stacking O-N-O (silicon oxide-silicon nitride-silicon oxide).

In the step of S103, based on a first photomask, a bit line structure 30 is formed in the stacked structure 20, and a capacitor region 40 is formed in the periphery region.

Referring to FIG. 1, the bit line structure 30 extends in the vertical direction Z and runs through the stacked structure 20. A row of bit line structures 30 are formed outside each of two opposite sides of the capacitor region 40 in a first direction X.

Still referring to FIG. 1, each of the composite layers of the capacitor region 40 includes first electrode plates 41. The first electrode plates 41 are distributed at intervals on two opposite sides of the composite layer of the capacitor region 40 in the first direction X. Adjacent first electrode plates 41 are not directly connected to each other.

Still referring to FIG. 1, each of the first electrode plates 41 protrudes toward an outer side of the capacitor region 40, that is, each of the first electrode plates 41 protrudes toward a corresponding bit line structure 30, and is connected to the corresponding bit line structure 30.

It can be understood that the first electrode plate 41 protrudes outward, which facilitates connection to the bit line structure 30 located on the outer side, thereby benefitting processing and manufacturing of the semiconductor structure. In addition, the first electrode plate 41 protrudes outward to form a curved electrode plate shape. In this way, an area between the electrode plates can be increased, and thus the capacity of the capacitor NICAP is increased.

In some embodiments of the present disclosure, with reference to FIG. 1 and FIG. 2, a memory cell region 50 of the array region can further be formed based on the first photomask.

In FIG. 2, a projection of the memory cells 51 and the isolation structure 60 that are between two rows of bit line structures 30 on the horizontal plane is the same as a projection of the capacitor region 40 in FIG. 1 on the horizontal plane. In addition, the memory cell 51 shown in FIG. 2 may be a capacitor in the memory cell, and the capacitor in the memory cell and the capacitor (that is, the capacitor region 40) in the periphery region are formed in a same layer. Therefore, a same photomask can be adopted to form the capacitor region 40 and the memory cell region 50. In this way, a quantity of photomasks needed can be reduced, and costs can be saved.

In some embodiments of the present disclosure, a method for forming the bit line structure 30 and the capacitor region 40 includes steps S201 to S204.

In the step of S201, based on the first photomask, a first cavity 401 and bit line holes 301 are formed in the stacked structure.

In the step of S202, the first cavity 401 and the bit line hole 301 are filled with a sacrificial material.

In FIG. 3A, FIG. 3B, and FIG. 3C, the first cavity 401 and the bit line hole 301 are filled with a sacrificial material. Both the first cavity 401 and the bit line hole 301 run through the stacked structure 20 in the vertical direction Z. A row of bit line holes 301 are formed outside each of two opposite sides of the first cavity 401 in the first direction X. Protruding grooves 402 distributed at intervals are formed at intersections between two opposite side faces of the first cavity 401 in the first direction X and the composite layer.

In the step of S203, the sacrificial material in the bit line hole 301 is removed, and the bit line structure 30 is formed in the bit line hole 301.

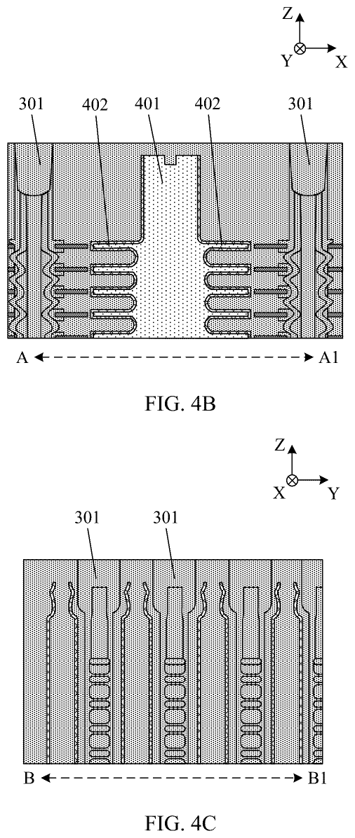

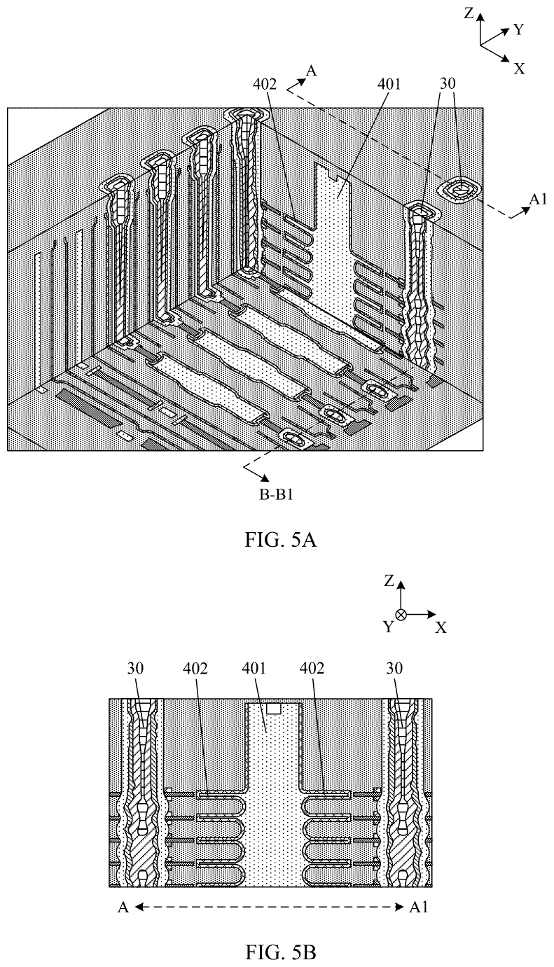

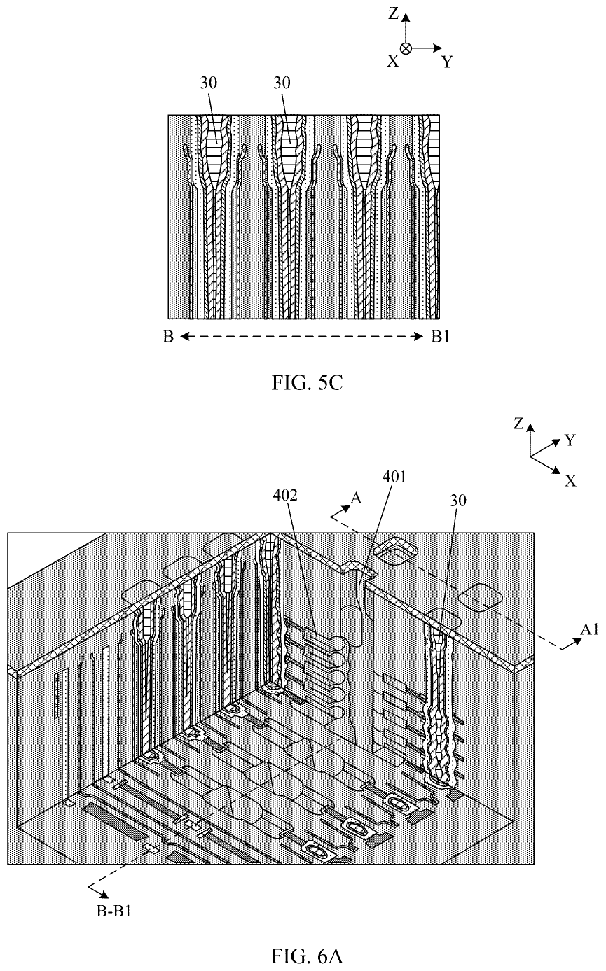

Referring to FIG. 4A and FIG. 5A, after the sacrificial material in the bit line hole 301 is removed, one or more layers of conductive material can be deposited sequentially in the bit line hole 301 to form the bit line structure 30. The conductive material may include one or more of titanium (Ti), titanium nitride (TiN), or tungsten (W). An etching selectivity ratio between the conductive material of the bit line structure 30 and a dielectric material has a relatively large difference. In this way, selective etching of the conductive material can be ensured to form the bit line structure 30. The dielectric material may be silicon nitride (SiN) or silicon oxide (SiO).

In the step of S204, the sacrificial material in the first cavity 401 is removed, and the capacitor region 40 is formed in the first cavity 401, where the first electrode plate 41 is formed in the protruding groove 402.

It should be noted that in a procedure of forming the bit line structure 30 in the bit line hole 301, a protective layer can be formed above the first cavity 401 to prevent the first cavity 401 from being affected. Correspondingly, in a procedure of forming the capacitor region 40 in the first cavity 401, a protective layer can be formed above the bit line structure 30 to prevent the bit line structure 30 from being affected.

In some embodiments of the present disclosure, the foregoing step S204 can be implemented through steps S301 to S305.

In the step of S301, a first conductive layer is deposited on an inner side wall of the first cavity 401.

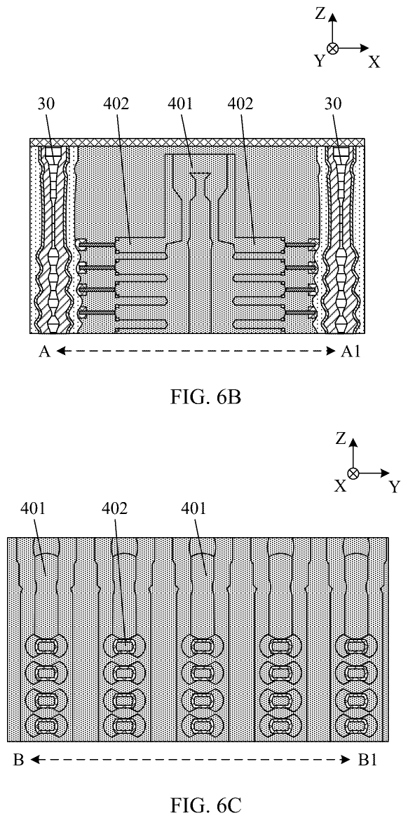

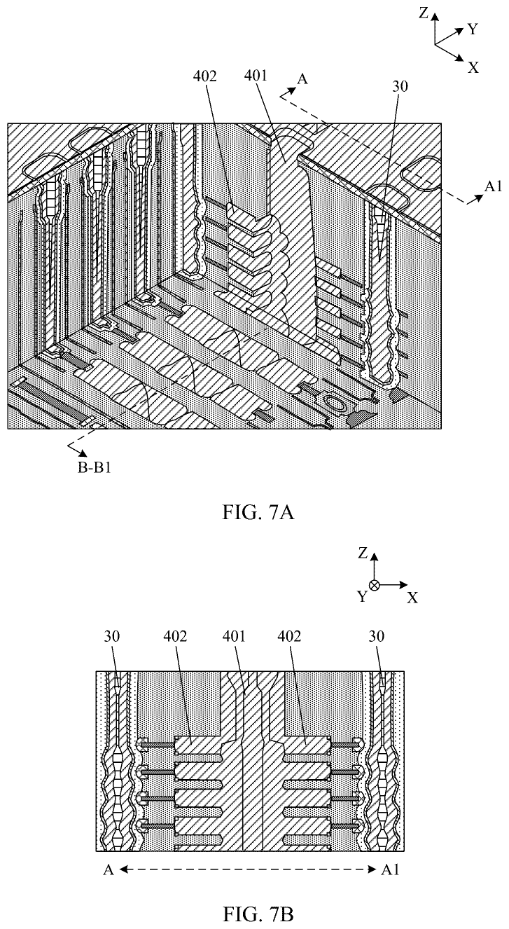

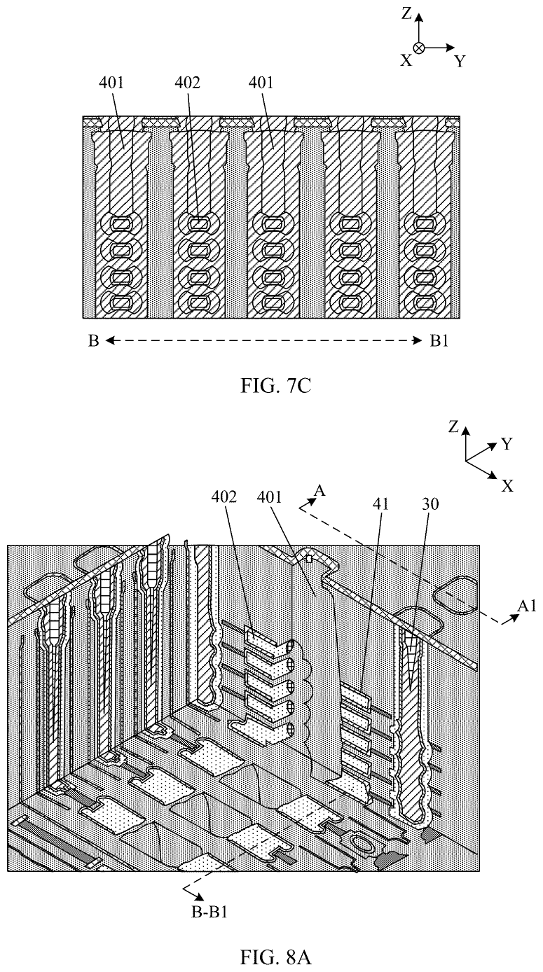

With reference to FIG. 6A and FIG. 7A, after the sacrificial material in the first cavity 401 is removed, a conductive layer (that is, the first conductive layer) can be deposited on the inner side wall of the first cavity 401. The first conductive layer covers an inner side wall of the protruding groove 402 and an inner side wall of another region in the first cavity 401. The material of the first conductive layer may include titanium (Ti) and/or titanium nitride (TiN).

In the step of S302, etching is performed in the first cavity 401 to partially remove the first conductive layer, and the first conductive layer in the protruding groove 402 is retained and exposed to form the first electrode plate 41.

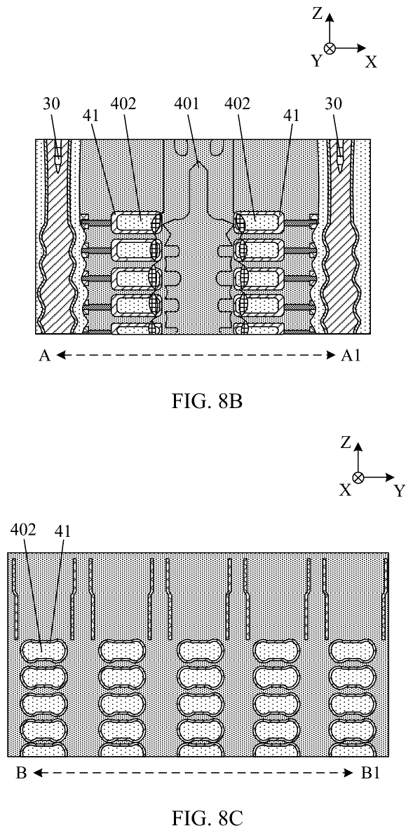

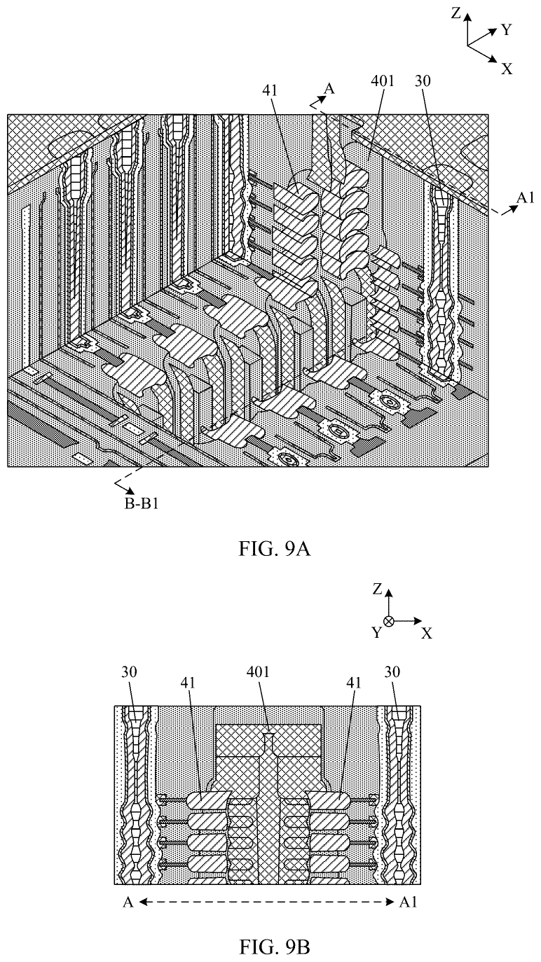

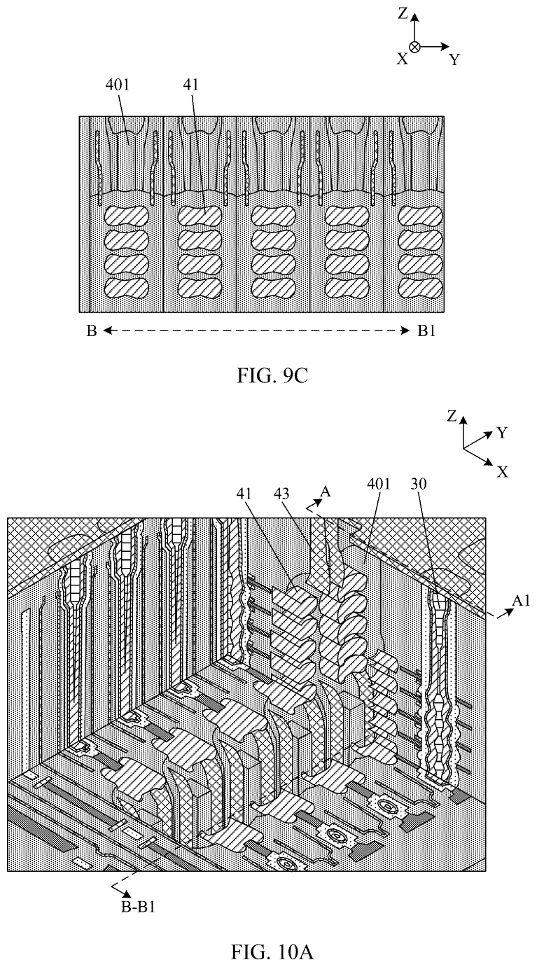

With reference to FIG. 8A and FIG. 9A, etching can be performed in the first cavity 401, only the first conductive layer covering the inner side wall of the protruding groove 402 is retained, the remaining first conductive layer is removed, and the first conductive layer in the protruding groove 402 is exposed. In this way, the first electrode plates 41 arranged at intervals are formed. Because the protruding grooves 402 are arranged at intervals, adjacent first electrode plates 41 are not directly connected to each other.

In the step of S303, a dielectric layer 43 is deposited on the inner side wall of the first cavity 401.

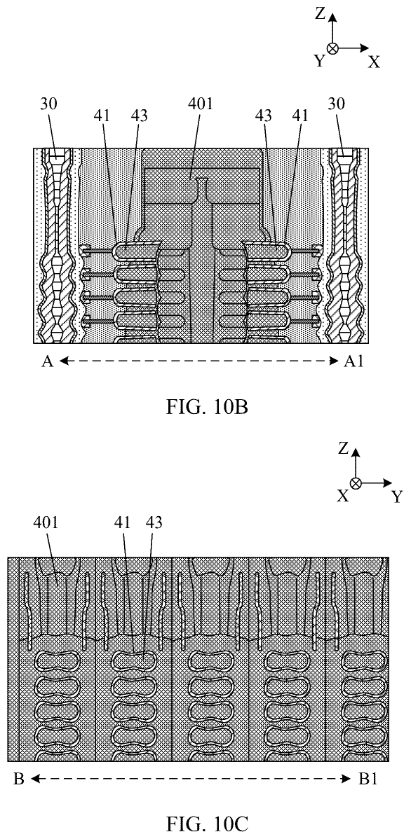

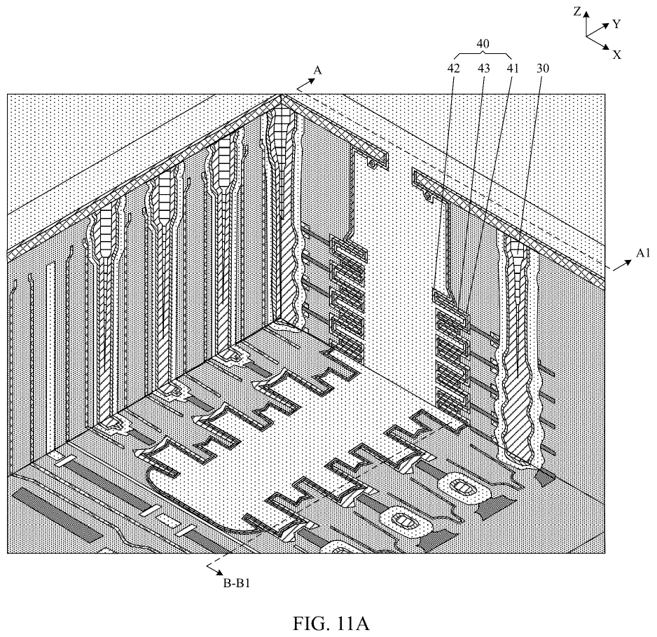

Referring to FIG. 10A, FIG. 10B, and FIG. 10C, the dielectric layer 43 covers the inner side wall of the first cavity 401, and also covers an exposed surface of the first electrode plate 41. The material of the dielectric layer 43 may include a high-k (high-k) material, and the capacity of the capacitor can be increased by adopting the high-k material.

In the step of S304, a second conductive layer covering the dielectric layer 43 is deposited on the inner side wall of the first cavity 401 to form a second electrode plate 42.

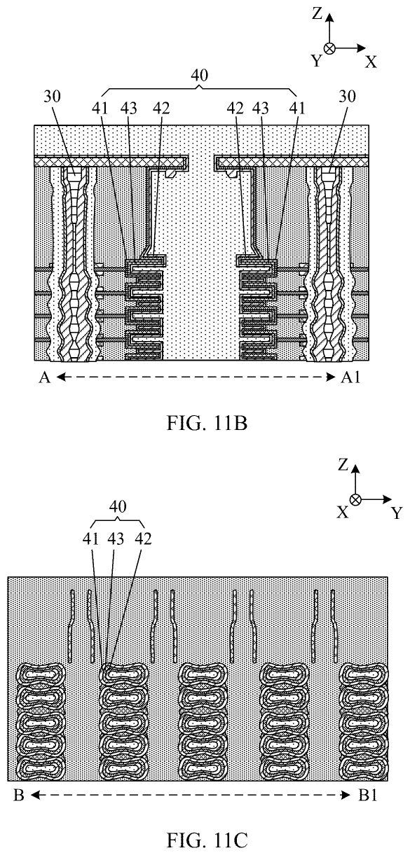

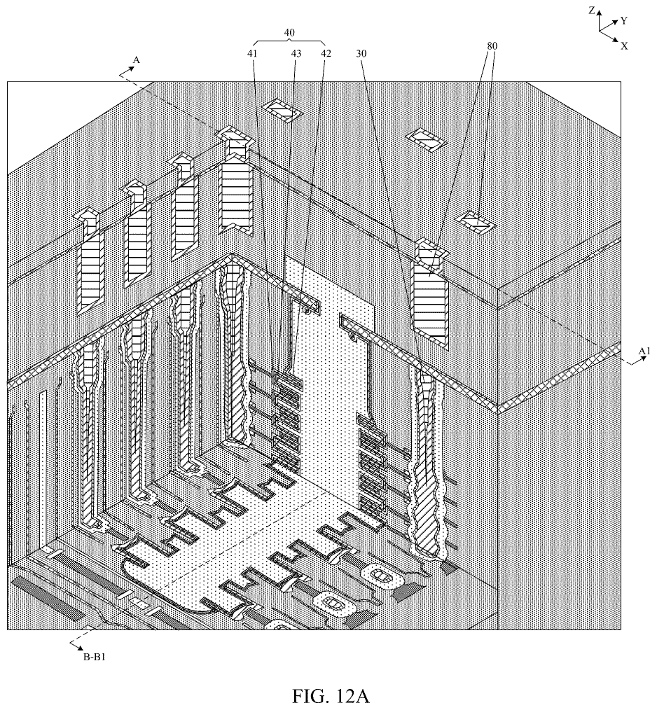

Referring to FIG. 11A, FIG. 11B, and FIG. 11C, on the inner side wall of the first cavity 401, the second electrode plate 42 covers a surface of the dielectric layer 43, so that a capacitor NICAP can be formed. The material of the second electrode plate 42 may include titanium (Ti) and/or titanium nitride (TiN).

In the embodiments of the present disclosure, in a composite layer of each capacitor region 40, the second electrode plate 42 is an integral electrode plate, that is, a same second electrode plate 42 and multiple first electrode plates 41 form a capacitor. In this way, it is equivalent to connecting multiple capacitors in parallel, so that a capacitor with relatively large capacity can be implemented.

In addition, in a composite layer of each capacitor region 40, the second electrode plate 42 is located on the inner side to form a closed structure. In this way, compared with a sleeve capacitor or a plate capacitor, a size occupied by a capacitor can be effectively reduced, thereby benefitting improvement of a degree of integration.

In the step of S305, the first cavity 401 is filled with a semiconductor material. The semiconductor material filled in the first cavity 401 can play a supporting and isolating role. The semiconductor material may include polysilicon.

In some embodiments of the present disclosure, the foregoing step S302 can be implemented through steps S401 to S403.

In the step of S401, the protruding groove 402 is filled with a sacrificial material.

In the embodiments of the present disclosure, a sacrificial material can be filled in the first cavity 401 (including the protruding groove 402 and other regions); then, etching is performed, only the sacrificial material in the protruding groove 402 is retained, and the sacrificial material in other regions is removed. In this way, the structure shown in FIG. 8A, FIG. 8B, and FIG. 8C is obtained. Because the protruding groove 402 protrudes toward an outer side of the first cavity 401, the sacrificial material in the protruding groove 402 can be retained in an etching procedure.

In the step of S402, etching is performed in the first cavity 401 to partially remove the first conductive layer, and the first conductive layer in the protruding groove 402 is retained.

In the embodiments of the present disclosure, because the protruding groove 402 is filled with the sacrificial material, in a procedure of etching the first conductive layer, the first conductive layer in the protruding groove 402 is protected by the sacrificial material and thus is retained.

In the step of S403, the size of the first cavity 401 in the first direction X is enlarged to expose the first conductive layer in the protruding groove 402, and the sacrificial material in the protruding groove 402 is removed.

In the embodiments of the present disclosure, an exposed side wall of the first cavity 401 can be etched to enlarge the size of the first cavity 401 in the first direction X. For example, an etching solution with an etching selectivity ratio can be injected into the first cavity 401 to selectively etch a side wall of the first cavity 401. For another example, a plasma beam can be adopted to bombard the side wall of the first cavity 401, so as to etch the side wall of the first cavity 401.

In some embodiments of the present disclosure, after the foregoing step S103, the forming method for a semiconductor structure further includes step S104.

In the step of S104, a back-end interconnect 80 extending in the vertical direction Z is formed above the capacitor region 40 and above the bit line structure 30.

Referring to FIG. 12A, FIG. 12B, and FIG. 12C, the material of the back-end interconnect 80 includes a metal material, such as tungsten (W).

It should be noted that, the semiconductor structure and the forming method therefor provided in the embodiments of the present disclosure can be applied to a dynamic random access memory DRAM, providing a new solution for three-dimensional memory products. The capacitor NICAP (that is, the capacitor region 40) in the periphery region and the memory cell are located in a same composite layer. The capacitor NICAP in the periphery region is configured to serve as a power supply or perform signal processing in the periphery region to perform frequency modulation, reduce noise, increase capacitance, and implement a separate 1C test structure.

It should be noted that in this specification, the terms “include”, “comprise”, or any other variant thereof are intended to cover non-exclusive inclusion, so that a procedure, method, article, or apparatus including a series of elements includes not only those elements but also other elements that are not expressly listed, or further includes elements inherent to such a procedure, method, article, or apparatus. An element preceded by “includes a . . . ” does not, without more constraints, preclude the presence of additional identical elements in the procedure, method, article, or apparatus including the element.

The sequence numbers of the foregoing embodiments of the present disclosure are merely for the purpose of description, and are not intended to indicate priorities of the embodiments. The methods disclosed in the several method embodiments provided in the present disclosure may be randomly combined when there is no conflict, to obtain new method embodiments. The features disclosed in the several product embodiments provided in the present disclosure may be randomly combined when there is no conflict, to obtain new product embodiments. The features disclosed in the several method or device embodiments provided in the present disclosure may be randomly combined when there is no conflict, to obtain new method embodiments or new device embodiments.

The foregoing descriptions are merely specific implementations of the present disclosure, but are not intended to limit the protection scope of the present disclosure. Any variation or replacement readily figured out by a person skilled in the art within the technical scope disclosed in the present disclosure shall fall within the protection scope of the present disclosure.

What is claimed is:

1. A semiconductor structure, wherein the semiconductor structure comprises a semiconductor substrate, a stacked structure, and a bit line structure;
the stacked structure and the bit line structure are located on the semiconductor substrate;
the semiconductor substrate comprises an array region and a periphery region;
the stacked structure comprises separation layers and composite layers that are alternately stacked in a vertical direction; and the bit line structure extends in the vertical direction and runs through the stacked structure; and
the stacked structure located in the periphery region comprises a capacitor region; and a row of bit line structures are formed outside each of two opposite sides of the capacitor region in a first direction, wherein
each of the composite layers of the capacitor region comprises first electrode plates; the first electrode plates are distributed at intervals on two opposite sides of the composite layer of the capacitor region in the first direction and protrude outward; and each of the first electrode plates is connected to a corresponding bit line structure.

2. The semiconductor structure according to claim 1, wherein the composite layer of the capacitor region further comprises a dielectric layer and a second electrode plate;
the second electrode plate is located on an inner side of the composite layer of the capacitor region; and the dielectric layer is located between the first electrode plate and the second electrode plate; and
an inner side of the second electrode plate is filled with a semiconductor material.

3. The semiconductor structure according to claim 1, wherein the composite layer of the capacitor region further comprises a contact plug; and
the contact plug is located between the first electrode plate and the bit line structure; and each of the first electrode plates is connected to a corresponding bit line structure through the contact plug.

4. The semiconductor structure according to claim 1, wherein the stacked structure located in the array region comprises a memory cell region;
memory cells arranged in an array are provided in the memory cell region;
one bit line structure is formed between two opposite memory cells in the first direction; and
the two memory cells are connected to a corresponding bit line structure; and
both the capacitor region and the memory cell region are formed based on a first photomask.

5. The semiconductor structure according to claim 1, wherein the semiconductor structure further comprises a back-end interconnect;
the back-end interconnect extends in the vertical direction; and
the back-end interconnect is located above the capacitor region and above the bit line structure.

6. A forming method for a semiconductor structure, comprising:
providing a semiconductor substrate, the semiconductor substrate comprising an array region and a periphery region;
forming a stacked structure on the semiconductor substrate, the stacked structure comprising separation layers and composite layers that are alternately stacked in a vertical direction; and
forming a bit line structure and a capacitor region in the stacked structure in the periphery region based on a first photomask, wherein the bit line structure extends in the vertical direction and runs through the stacked structure; a row of bit line structures are formed outside each of two opposite sides of the capacitor region in a first direction; and each of the composite layers of the capacitor region comprises first electrode plates; the first electrode plates are distributed at intervals on two opposite sides of the composite layer of the capacitor region in the first direction and protrude outward; and each of the first electrode plates is connected to a corresponding bit line structure.

7. The forming method for a semiconductor structure according to claim 6, wherein a method for forming the bit line structure and the capacitor region comprises:
forming a first cavity and bit line holes in the stacked structure based on the first photomask;
both the first cavity and the bit line holes running through the stacked structure in the vertical direction; and a row of bit line holes being formed outside each of two opposite sides of the first cavity in the first direction; and protruding grooves distributed at intervals being formed at intersections between two opposite side faces of the first cavity in the first direction and the composite layer;
filling the first cavity and the bit line hole with a sacrificial material;
removing the sacrificial material in the bit line hole, and forming the bit line structure in the bit line hole; and
removing the sacrificial material in the first cavity, and forming the capacitor region in the first cavity, wherein the first electrode plate is formed in the protruding groove.

8. The forming method for a semiconductor structure according to claim 7, wherein the forming the capacitor region in the first cavity comprises:
depositing a first conductive layer on an inner side wall of the first cavity;
performing etching in the first cavity to partially remove the first conductive layer, and retaining and exposing the first conductive layer in the protruding groove to form the first electrode plate;
depositing a dielectric layer on the inner side wall of the first cavity;
depositing a second conductive layer covering the dielectric layer on the inner side wall of the first cavity to form a second electrode plate; and
filling the first cavity with a semiconductor material.

9. The forming method for a semiconductor structure according to claim 8, wherein the performing etching in the first cavity to partially remove the first conductive layer, and retaining and exposing the first conductive layer in the protruding groove comprises:
filling the protruding groove with a sacrificial material;
performing etching in the first cavity to partially remove the first conductive layer, and retaining the first conductive layer in the protruding groove; and
enlarging a size of the first cavity in the first direction to expose the first conductive layer in the protruding groove, and removing the sacrificial material in the protruding groove.

10. The forming method for a semiconductor structure according to claim 6, wherein after the bit line structure and the capacitor region are formed, the method further comprises:
forming a back-end interconnect extending in the vertical direction above the capacitor region and above the bit line structure.
